(19) United States
(12) Patent Application Publication
(10) Pub. No.: US 2006/0175616 A1
(43) Pub. Date: Aug. 10, 2006

(54) Pre-oxidized protective layer for lithography

(76) Inventors: Manish Chandhok, Portland, OR (US); Ming Fang, Portland, OR (US); Robert Bristol, Portland, OR (US)

Correspondence Address: FISH & RICHARDSON, PC, P.O. BOX 1022, MINNEAPOLIS, MN, 55440-1022, US

(21) Appl. No.: 11/052,966

(22) Filed: Feb. 7, 2005

(51) Int. Cl. H01L 21/00; H01L 33/00; H01L 31/12

(52) U.S. Cl. 257/79; 438/29

(57) ABSTRACT

An optical component for use in, e.g., an extreme ultraviolet (EUV) lithography system, may include a pre-oxidized protective layer. The protective layer may be photocatalytic, and may be substantially amorphous to provide a diffusion barrier. The protective layer may be, e.g., a metal oxide such as titanium dioxide or molybdenum oxide.

### BACKGROUND

Lithography is used in the fabrication of semiconductor devices. In lithography, light is used to transfer a pattern based on a mask or reticle pattern to a layer on a substrate. The substrate is subsequently processed to formed patterned device features.

In order to pattern relatively large device features, visible light may be used. However, for smaller device features, other lithography techniques may be needed. One technique that may be used to pattern small device features is Extreme Ultraviolet (EUV) lithography. EUV lithography uses short wavelength (e.g., 11-15 nm), high energy (e.g., 92 eV) EUV radiation.

Because most materials readily absorb EUV radiation, EUV systems often incorporate reflection optics rather than transmission optics. In order to protect the optical components from interactions that may change their optical properties (e.g., interactions with the highly energetic EUV photons), component surfaces may be covered with material referred to as a “capping layer.”

EUV light may be produced using a small, hot plasma that will efficiently radiate at a desired wavelength, e.g., in a range of approximately 11 nm to 15 nm. The plasma may be created in a vacuum chamber; for example, by driving a pulsed electrical discharge through a target material or by focusing a pulsed laser beam onto a target material. The plasma generates light of an appropriate wavelength, which may then be reflected by optical components for use in a lithography process.

### BRIEF DESCRIPTION OF THE DRAWINGS

FIG. 1 is a sectional view of a multilayer collector mirror including a silicon capping layer.

FIG. 2 is a sectional view of an optical component including a pre-oxidized protective layer, according to some implementations.

FIG. 3 is a block diagram of a light source chamber, according to some implementations.

FIG. 4 is a block diagram of a lithography system, according to some implementations.

FIG. 5A illustrates the creation of anodic and cathodic regions in a titanium dioxide capping layer during an illumination in a lithography tool.

FIG. 5B illustrates a photocatalytic conversion of hydrocarbons during an illumination operation in a lithography tool.

Like reference symbols in the various drawings indicate like elements.

### DETAILED DESCRIPTION

Systems and techniques provided herein may allow for reduced variability in the optical characteristics of lithography systems. This may be particularly useful in EUV systems, which use higher energy photons than visible light systems. For an EUV system, factors that change optical characteristics of system components (e.g., reduce component reflectivity) may impact the lifetime of the components, and result in higher cost of ownership.

Deposition and oxidation may affect the characteristics of optical components. For an EUV system, both or either of the protective capping layer material and the underlying optical material may become oxidized. For example, oxygen or oxygen-containing molecules may diffuse through the protective material and react with the optical material to form an oxide.

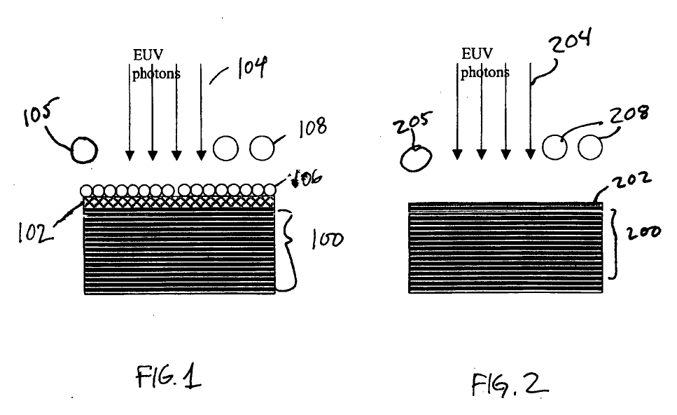

FIG. 1 illustrates deposition and oxidation processes for a multilayer collector mirror 100 with a silicon capping layer 102. EUV optical components such as mirror 100 generally incorporate multilayer interference structures; for example, structures with on the order of forty bi-layers of molybdenum and silicon (referred to as Mo/Si bi-layers).

Deposition may also occur in EUV systems. EUV systems typically operate in vacuum (e.g., ultra-high vacuum or UHV). However, trace amounts of hydrocarbons 105 and/or water 108 may still be present in the light source chamber during operation. This leads to water and/or hydrocarbons being adsorbed on component surfaces. Highly energetic EUV photons 104 may cause hydrocarbon “cracking;” that is, breaking down larger hydrocarbon molecules into smaller units. This may result in the deposition of carbon 106 on the optical surfaces.

Oxidation of the protective capping layer and/or the underlying material may occur due to (for example) EUV-induced breakdown of water molecules 108 into hydrogen and oxygen. Capping layer 102 and/or one or more layers of the multi-layer mirror 100 may react with the thus liberated oxygen to form an oxide material.

Mechanisms such as carbon deposition and oxidation of a silicon capping layer may reduce the reflectivity of the optics over time, thereby decreasing the efficiency of the light source and reducing the lifetime of the EUV optics. Ruthenium (Ru) has a lower oxidation rate than silicon, and may be used as an alternate capping layer material. However, the oxidation rate of ruthenium is still high enough to reduce the reflectivity of the optical components by about, for example, 1% over 200 hours. This reduction in reflectivity may be unacceptably rapid. For example, some projected systems target a 1% reflectivity change over 30,000 hours.

In some cases, the changes that occur due to deposition, oxidation, and the like may be mitigated by processing the component. For example, a cleaning process may be used to remove deposited carbon. However, oxidation is generally not amenable to a cleaning process. Instead, an etching process may be required to remove oxidized portions of the components. Component processing may increase the cost of ownership for a lithography system, and may increase system downtime.

Additionally, a “self-cleaning” process may occur for carbon deposited on a surface, in the presence of H₂O or other oxygen-containing molecules. Oxygen (O₂) produced from the breakdown of H₂O may react with the carbon to produce either carbon monoxide (CO) or carbon dioxide (CO₂), which evolves and may subsequently be removed by the vacuum system. However, there is typically a higher concentration of water in the chamber than hydrocarbons, e.g., on the order of two orders of magnitude. Consequently, a substantial amount of oxygen may remain after the carbon is consumed. The remaining oxygen may cause oxidation of the capping layer and underlying multilayer optics.

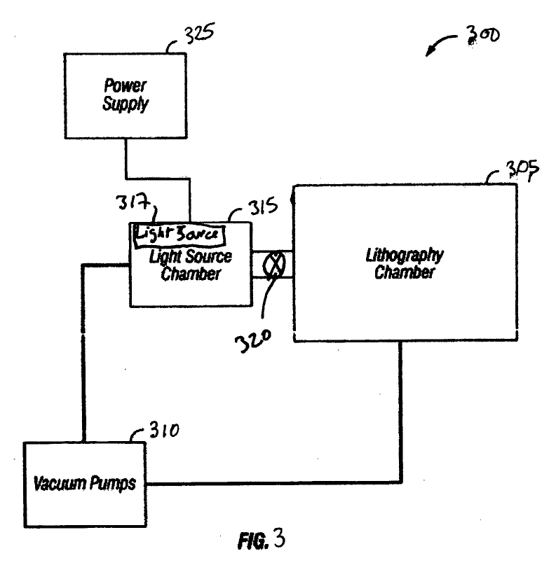

Systems and techniques described herein may provide for more stable optical characteristics, without requiring additional procedures such as cleaning and/or etching procedures. FIG. 2 shows a cross-sectional view of a portion of an optical component 200 including a protective layer 202 comprising a pre-oxidized material. The current inventors recognized that pre-oxidized material may be provide a dual benefit: first, it may be resistant to further oxidation; second, it may provide a barrier to oxidation of the underlying material (e.g., multilayer Mo/Si material for EUV reflection).

Herein, the term “pre-oxidized” refers to a material that is oxidized in a controlled manner, so that further oxidation is substantially reduced or prevented. For example, a pre-oxidized material may be formed using a controlled thermal oxidation process. For example, a pre-oxidized titanium oxide material may be formed by depositing titanium, then increasing the temperature of the titanium in the presence of oxygen (e.g., in the presence of an oxygen-containing molecule) until the titanium is substantially oxidized. A pre-oxidized material may also be formed by depositing the oxidized material.

In contrast, some materials may form a native oxide on a surface exposed to, for example, air. However, these native oxides are generally thin oxide layers. For example, when freshly cleaved silicon is exposed to an oxidizing ambient at room temperature, it will form a very thin oxide layer (about 1-2 nm). Because un-oxidized material remains beneath the surface oxide layer, further oxidation may occur.

The current inventors further realized that additional benefits may be obtained if the capping layer comprises a material having photocatalytic properties. As noted above, hydrocarbon molecules 205 may be broken down by EUV photons 204, resulting in carbon deposition. As a photocatalyst, the material may operate in response to EUV photons during illumination to promote reaction between adsorbed carbon and oxygen liberated from water vapor in the chamber, thereby speeding up removal of the carbon. Herein, the term “photocatalytic” refers to a material that has a bandgap sufficient to break down a water molecule into a proton (H⁺ ion) and hydroxyl anion (OH⁻). The energy required corresponds to a material bandgap of about 2 eV or greater. For example, materials with bandgaps in the range from about 2 eV to about 4 eV may be said to be photocatalytic.

The pre-oxidized capping material may be in a substantially amorphous state, which may provide a smoother surface than a crystalline material and reduce or eliminate grain boundary paths for oxygen diffusion. In some implementations, the capping layer may have a thickness in a range of about 1 nm to about 8 nm.

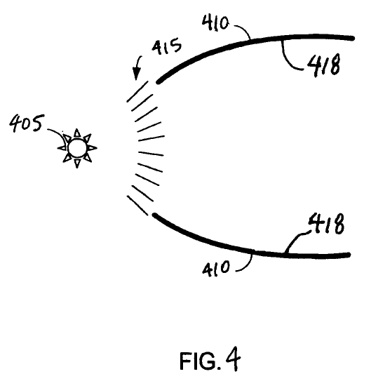

As noted above, optical components including pre-oxidized protective material may be used in an EUV lithography system. FIG. 3 shows an implementation of a lithography system 300 that may be used to form patterned features on a wafer as follows. A resist-coated wafer and a patterned mask may be placed in a lithography chamber 305. Note that although the term “mask” is used herein, it is used generally to refer to masks, reticles, and any other device and/or structure that is used to pattern semiconductor material.

The pressure in the lithography chamber 305 may be reduced by one or more vacuum pumps 310. A light source chamber 315 includes a light source 317 to produce light of an appropriate wavelength. During lithography, light source chamber 315 is in optical communication with the lithography chamber 305. The pressure in the light source chamber may also be reduced by vacuum pumps 310 (and/or a separate vacuum system). The light source chamber and lithography chamber may be separated by a valve 320, so that different environments may be provided within the different chambers.

The light source chamber 315 may be an extreme ultraviolet (EUV) chamber, and light source 317 may be an EUV light source. A power supply 325 may be connected to light source 317 to supply energy for creating an EUV photon emitting plasma, which provides EUV light for lithography. The EUV light may have a wavelength in a range of about 11 nm to about 15 nm; e.g., 13.5 nm.

Light source 317 may be a plasma light source, e.g., a laser-produced plasma (LPP) source, discharge-produced plasma (DPP) source, or a pinch plasma source. Plasma-producing components of the EUV source, such as electrodes, may excite a gas to produce EUV radiation. The gas may be, e.g., an ionized cluster of a rare gas such as xenon (Xe) or a metal vapor such as tin (Sn), lithium (Li), or compounds including these species.

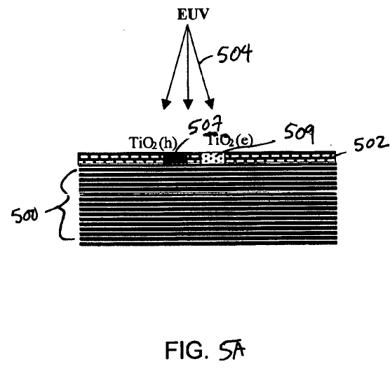

FIG. 4 shows a sectional view of an exemplary EUV chamber, according to some implementations. Inside the EUV chamber are the light source 405 (e.g., a DPP source), and optical components such as collector mirrors 410 for collecting and directing the EUV light 415 for use in the lithography chamber 105. The collector mirrors 410 may be, for example, coated with a bulk metal and operate with grazing angle reflections, as shown, or may be coated with a multi-layer material and operate with near-normal incidence reflections. Mirrors 410 are shaped and sized to be mounted in the EUV chamber to direct light for use in a lithography process.

Mirrors 410 may include pre-oxidized protective material on at least an optical surface 418, where optical surface 418 receives light 415 from source 405. In some implementations, the protective material may include titanium dioxide (TiO₂). Titanium in titanium dioxide is in a 4+ state which is a very stable, oxidation resistant state.

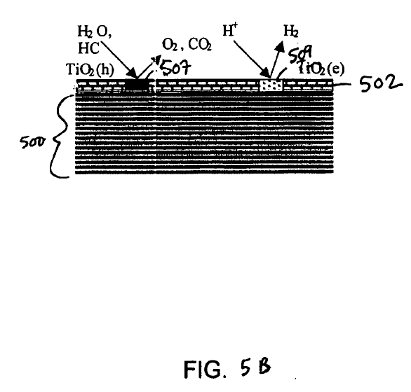

FIGS. 5A and 5B illustrate the reaction mechanism of oxidation and reduction on an exemplary titanium dioxide capping layer 502. Illumination by EUV photons (hν) 504 may produce photoanode sites 507 (having excess of holes and designated “TiO₂(h)”) and photocathode sites 509 (having excess of electrons and designated “TiO₂(e)”) in the titanium dioxide layer 502;
TiO₂+hν→TiO₂(h)+TiO₂(e). (1)

The photoanode sites 507 may decompose water vapor to generate hydrogen and oxygen;
TiO₂(h)+H₂O→½O₂+2H⁺. (2)

The titanium dioxide may act as a photocatalyst to assist in the oxidation of hydrocarbons;
O₂+HC→CO₂+H₂0. (3)

The remaining electrons (e⁻) may combine with the hydrogen ions (from Eq. (2));
2H⁺+2e⁻→H₂.

The rate of oxidation of hydrocarbons such as salicylic acid and methylene blue assisted by UV exposure in water has been reported at the level of 10⁻⁸ moles/min·cm² in the presence of titanium dioxide. The typical hydrocarbon content in an EUV lithography (EUVL) tool may be about 10⁻¹⁰ Torr. Assuming the hydrocarbon has a mass of about 55 AMU (atomic mass units) and an oxidation rate approximating that given above, hydrocarbon cleaning may be achieved in a few seconds.

The reflectivity of 40 bi-layers of Mo/Si capped with silicon may have a maximum theoretical reflectivity of 74%. The addition of a 2 nm of a substantially smooth capping layer, such as titanium dioxide, molybdenum oxide (MoO₃), or other pre-oxidized material, may result in a drop in reflectivity of less than 1% (see Table 1).

TABLE 1

| Capping Layer Material | Theoretical Reflectivity |
|---|---|
| 4 nm Silicon | 74% |
| 2 nm TiO₂ | 73% |
| 2 nm MoO₃ | 73.8% |

The current inventors realized that a number of other factors may improve the characteristics of optical components including pre-oxidized protective layers. For example, a substantially smooth capping layer material may reduce reflectivity loss attributable to factors other than the optical properties of the layer itself. Further, using an amorphous capping layer material may reduce oxidation of the underlying material by acting as a diffusion barrier. Depositing capping layer materials at relatively low temperatures may reduce or substantially prevent thermally-activated interdiffusion of Mo/Si multilayers.

An optical component including a substantially pre-oxidized protective layer may be formed as follows. A multi-layer substrate may be provided. The multi-layer substrate may be an interference structure comprising alternating layers, such as alternating molybdenum and silicon layers. The substrate may be shaped and sized for use as an optical component in a lithography system, and may have one or more optical surfaces (e.g., surfaces which interact with radiation for lithography).

A pre-oxidized protective layer may be formed at least adjacent to the optical surfaces of the substrate. That is, surfaces of the substrate that generally do not interact with radiation need not be adjacent to the protective layer. However, in some implementations, the protective layer is formed over the entire substrate.

The thickness of the pre-oxidized protective layer may be selected so that the reflectivity of the resulting optical component is not unduly compromised, while the underlying material is protected. For example, in some implementations, layer thicknesses of about 1 nm to about 5 nm may be used.

In some implementations, a pre-oxidized protective layer may be formed over a silicon, ruthenium, or other layer. The silicon or other layer may provide additional protection from damage due to energetic photons for the optical component.

As noted above, in some implementations, the pre-oxidized protective layer comprises titanium dioxide. Many technologies have been proposed and investigated to synthesize a nano-scale titanium dioxide layer, including pulse laser-assisted evaporation, sputtering, spray pyrolysis, and atomic layer deposition. One method of forming a pre-oxidized protective layer may include forming a substantially amorphous layer using laser-assisted evaporation, with a substrate temperature of about 200° C. or less. A thickness of titanium dioxide continuous film less than 4 nm may be achieved with a surface roughness variation under 0.5 nm using laser-assisted evaporation. In addition, the amorphous phase of titanium dioxide may be obtained when the substrate temperature is under 200° C. This substrate temperature is low enough that substantial thermally activated inter-diffusion of optical layers (e.g., Mo/Si layers) does not occur.

Although only a few embodiments have been disclosed in detail above, other modifications are possible, and this disclosure is intended to cover all such modifications, and most particularly, any modification which might be predictable to a person having ordinary skill in the art.

For example, blocks in the flowcharts may be skipped or performed out of order and still produce desirable results. In other examples, different pre-oxidized materials than those discussed above may be incorporated in optical components. Optical components including pre-oxidized protective layers may be used in components outside of the light source chamber, such as those positioned in the lithography chamber during a lithography process. Although implementations have been described with respect to an EUV lithography system, pre-oxidized protective layers may be used for optical components of other lithography systems.

Also, only those claims which use the words “means for” are intended to be interpreted under 35 USC 112, sixth paragraph. Moreover, no limitations from the specification are intended to be read into any claims, unless those limitations are expressly included in the claims. Accordingly, other embodiments are within the scope of the following claims.

1. A device comprising:
an optical component shaped and sized to be mounted in an extreme ultra-violet lithography system, the optical component having an optical surface configured to reflect extreme ultra-violet light; and
a substantially pre-oxidized protective layer adjacent to at least the optical surface of the optical component, the protective layer comprising a photocatalytic material.

2. The device of claim 1, wherein the optical component comprises a multilayer material.

3. The device of claim 1, wherein photocatalytic material has a bandgap in the range from about 2 eV to about 4 eV.

4. The device of claim 1, wherein the protective layer comprises a metal oxide.

5. The device of claim 1, wherein the protective layer comprises at least one of titanium dioxide and molybdenum oxide.

6. The device of claim 1, wherein the protective layer is substantially amorphous.

7. The device of claim 1, wherein the protective layer is formed on an outer surface of the optical component.

8. The device of claim 1, wherein the protective layer has a thickness in the range from about 1 nm to about 8 nm.

9. The device of claim 1, wherein the protective layer has a surface roughness of less than about 0.5 nm.

10. A system comprising:
a radiation source;
an optical component shaped and positioned to receive light from the radiation source on an optical surface of the optical component and to reflect at least some light from the radiation source to a lithography region; and
a substantially pre-oxidized protective layer adjacent to at least the optical surface of the optical component, wherein the protective layer comprises a photocatalytic material.

11. The system of claim 10, wherein the radiation source comprises a plasma source.

12. The system of claim 10, wherein the radiation source comprises one or more electrodes.

13. The system of claim 10, further including a lithography chamber configured to be in optical communication with the radiation source during a lithography process.

14. The system of claim 13, further including another optical component shaped and positioned to receive light from the radiation source on an optical surface of the another optical component and to reflect at least some light to the lithography region; and
a substantially pre-oxidized protective layer adjacent to at least the optical surface of the another optical component.

15. The system of claim 14, wherein the another optical component is positioned in the lithography chamber, and wherein the another optical component is shaped and positioned to receive light from the radiation source reflected by the optical component.

16. A method, comprising:
providing a multi-layer substrate having an optical surface, the multi-layer substrate shaped and sized to reflect light in a lithography system from the optical surface; and
forming a pre-oxidized protective layer adjacent at least the optical surface of the multi-layer substrate, wherein the pre-oxidized protective layer comprises a photocatalytic material.

17. The method of claim 16, wherein said providing a multi-layer substrate comprises forming a multi-layer substrate comprising alternating layers comprising a first material and a second material.

18. The method of claim 17, wherein the first material comprises silicon and the second material comprises molybdenum.

19. The method of claim 16, wherein forming the pre-oxidized protective layer comprises forming a substantially amorphous layer.

20. The method of claim 16, wherein forming the pre-oxidized protective layer comprises forming a substantially smooth layer.

21. The method of claim 16, wherein forming the pre-oxidized protective layer comprises forming a metal oxide layer.
